(19) United States
(12) Patent Application Publication
(10) Pub. No.: US 2006/0255863 A1
(43) Pub. Date: Nov. 16, 2006

(54) Charge pump compensation techniques for sigma-delta fractional-N synthesizer

(75) Inventor: Larry Li, Irvine, CA (US)

Correspondence Address: LAW OFFICES OF CLEMENT CHENG, 17220 NEWHOPE STREET #127, FOUNTAIN VALLEY, CA, 92708, US

(73) Assignee: Comlent Holdings, Inc.

(21) Appl. No.: 11/126,450

(22) Filed: May 11, 2005

(51) Int. Cl. H03L 7/00

(52) U.S. Cl. 331/16

(57) ABSTRACT

A compensated fractional-N synthesizer has a voltage controlled oscillator providing a frequency output signal. The frequency divider divides the frequency output signal. It generates a frequency divider output divided signal. A frequency divider receives controlling signal from an adder receiving a fractional signal from a sigma-delta modulator and an independent integer number signal. A phase frequency detector compares a reference frequency signal with a frequency divider output divided signal outputting a phase frequency detector output to a charge pump. A loop filter for filtering a current provides filtered current to a voltage controlled oscillator. A charge pump provides current and a charge pump compensation means has a plurality of switch transistors providing an output signal to said charge pump. The charge pump compensation means receives the fractional signal from the sigma-delta modulator.

### BACKGROUND OF THE INVENTION

The demand for high data rate wireless devices has been growing over years, such as mobile telephones, digital audio, instrumentation and ADSL. It also had led to an abundance of wireless standards requiring high bandwidth analog-digital converters (ADCs) and a very fast settling time.

Sigma-delta modulator is an analog to digital converter, and it also provides the front end to an analog to digital converter. Most sigma-delta ADC's use switched-capacitor circuitry for applications. The implement of sigma-delta modulator can achieve rapid frequency changes, modulation, and low spurious signal and noise levels. When an analog signal is digitized, quantization error is introduced into the frequency spectrum. The sigma-delta function is to push the quantization error that is near the signal into a higher frequency band near the sampling frequency. After this is done the signal can be low pass filtered and the original signal can be restored in a digitized form.

In order to reduce the signal noise produced by the fast settling process, a wide loop bandwidth of frequency synthesizers must be designed with a loop filter. However, a wide loop bandwidth loop filter is not enough to filter the digitized noise after the noise shaping by the sigma-delta modulator.

FIG. 1 shows a prior art sigma-delta type fractional-N synthesizer phase-locked loop (PLL) circuitry. Phase-locked loop frequency synthesis is a technique for generating signals from a frequency variable voltage controlled oscillator (VCO). In a single loop PLL, an output signal from VCO is coupled to a VCO frequency divider which divides signals by a pre-selected integer number or randomly produced fractional number from a Sigma-Delta Modulator, if any, to provide a frequency divided signal to a phase detector (PFD). The phase frequency detector compares a divided voltage controlled oscillator signal with a pre-determined reference frequency (Fref) provided by another fixed frequency source oscillator or a reference clock. The prior art circuitry comprises a voltage controlled oscillator, a phase frequency detector, a charge bump, a loop filter and a VCO frequency divider. Said VCO divider receives output from a Sigma-Delta modulator.

Sigma Delta modulator introduces the fractional number into the traditional phase locked loop randomly. Due to the characteristics of Sigma Delta modulator noise shaping, digitized noise can be pushed to the relative high frequency, and then filtered by the loop filter. However, when loop bandwidth of the loop filter is large, it is difficult to filter out the high frequency noise generated by Sigma-Delta modulator.

U.S. Pat. No. 6,693,494 introduced a three-mode charge pump circuitry. By using its speed up mode mode, this prior design may achieve a faster switching or acquisition time and faster locking.

U.S. Pat. No. 6,693,494 provided a switching time PLL circuitry to narrow bandwidth to reduce phase noise.

U.S. Pat. No. 6,028,905 provided a charge pump steering system pre-limiting the charge pump charging time without sacrifice the total phasing and locking time.

### SUMMARY OF THE INVENTION

The present invention relates to a charge pump compensation circuitry coupled with a phase-locked loop (PLL) circuitry, more particularly to a charge pump compensation circuitry coupled with a fractional-N synthesizer PLL circuitry comprising a loop filter, a charge pump, a charge pump compensation means coupled with a phase-locked loop (PLL) circuitry.

A charge pump compensation technique is proposed with this invention to reduce the noise generated by Sigma-Delta noise shaping. With this invention, a frequency synthesizer can achieve a low phase noise in a fast settling time.

The object of the present invention is to provide charge pump compensation coupled with a fractional-N synthesizer circuitry with increased filtering capacity when the switching time increases.

Another object of this invention is to provide a fractional-N synthesizer of the sigma delta type, with lock detection and frequency noise filtering.

### BRIEF DESCRIPTION OF THE DRAWINGS

FIG. 1 is a block diagram of a prior art sigma-delta fractional-N synthesizer

FIG. 2 is a block diagram of a charge pump compensated sigma-delta fractional-N synthesizer, according to the present invention.

FIG. 3 is a detail circuitry for charge pump compensation means.

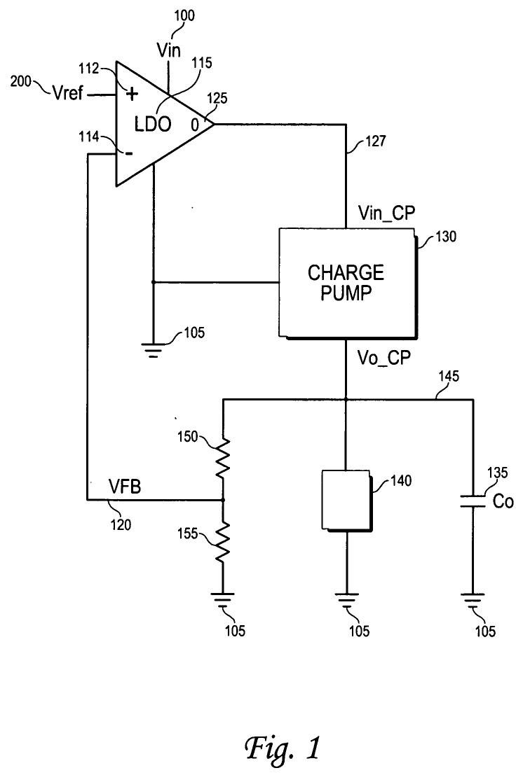

### CALL OUT LIST OF THE ELEMENTS

10 Prior Art PLL
11 Voltage Controlled Oscillator
12 VCO Frequency Divider
13 Phase Frequency Detector
14 Charge Bump
15 Loop Filter
121 Adder
122 Sigma-Delta Modulator
123 Fractional Number Input
124 Integer Number Input
131 Reference Frequency input
20 Block Diagram of Present Invention
21 Voltage Controlled Oscillator
22 VCO Frequency Divider
23 Phase Frequency Detector
24 Charge Bump
25 Charge Pump Compensation
26 Loop Filter
221 Adder
222 Sigma-Delta Modulator
223 Fractional Number Input
224 Integer Number Input
225 Sigma-Delta Modulator Output
231 Reference Frequency input
30 Charge Pump Compensation Circuit
31 Icp
32 Ground
33 Transistor Terminal
34 Transistor Terminal
35 Transistor Terminal
36 Output

### DETAILED DESCRIPTION OF THE PREFERRED EMBODIMENT

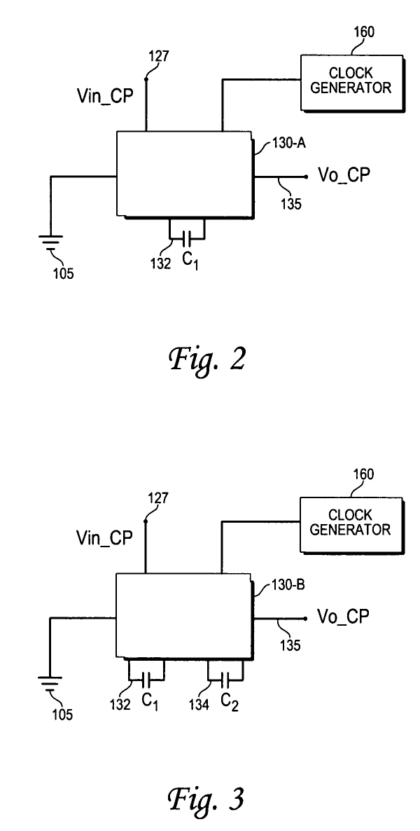

Referring to FIG. 2, the present invention comprises a phase locked loop circuit with the addition of a charge pump compensation means. The present invention comprises a voltage controlled oscillator 21 providing a frequency output signal, a frequency divider 22 for dividing said frequency output signal, a reference frequency input 231 (Fref), a phase frequency detector 23 (PFD) for comparing a reference signal 231 (Fref) with said divided frequency output signal, a loop filter means 26 for filtering a current to provide to the voltage controlled oscillator, a charge pump 24 for providing said current, and a charge pump compensation means 25 to compensate the charge pump.

The reference signal 231 (Fref) can be generated by a referenced clock or by another independent voltage controlled oscillator.

The frequency divider 22 receives a controlled signal from an adder 221. Said adder 221 combines an output signal from a sigma-delta modulator 222 and an independent integer number input signal. The sigma-delta modulator receives fractional numbers 223 then provides modulated fractional number input signal to the adder. The adder 221 receives, combines then produces controlling signal to the frequency divider 22. The sigma-delta modulator also produces a ΔN signal 225 to charge pump compensation means to provide extra filtering capacity.

The charge pump 24 is used to convert the logical signals from the PFD into analog signals for controlling the VCO. Ideally, when UP is active, the charge pump discharges the capacitors by mirroring the current Icp to the output as a sinking current for the duration of UP pulse. On the other hand, when DOWN is active, the charge pump charges the capacitors by mirroring Icp to the output as a sourcing current for the duration of the DOWN pulse. The charge pump is controllable by said phase detecting means 23. The charge pump also receives compensated signals from charge pump compensation means.

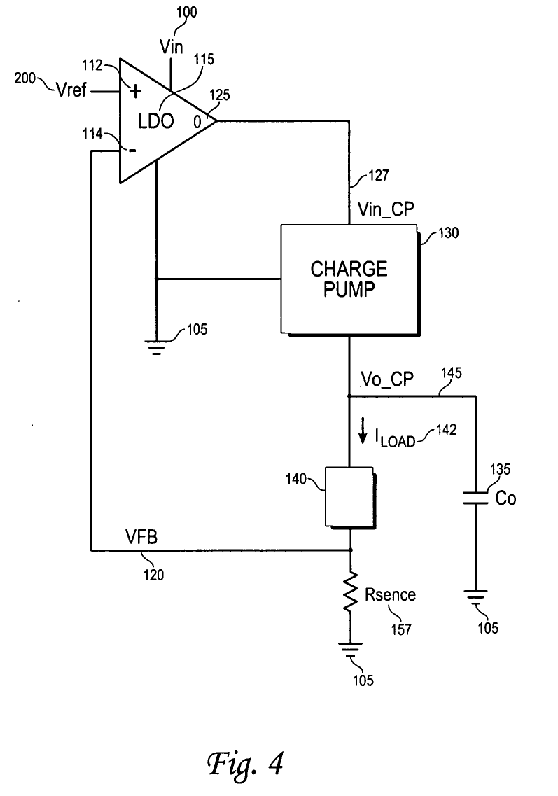

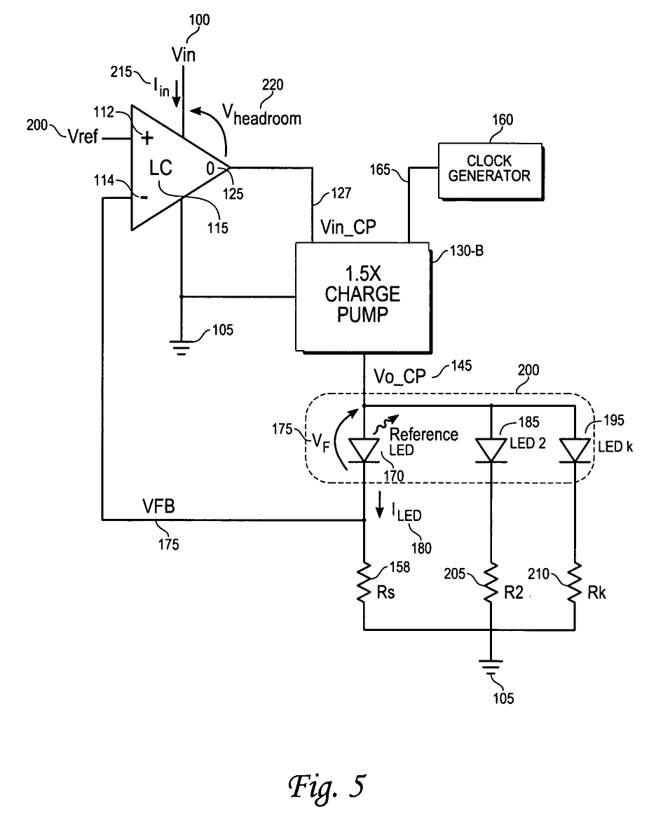

Referring to FIG. 3, the detail diagram for the charge pump compensation means 30, the means comprises a charge pump current 31 (Icp), and six metal-oxide semiconductor field effect transistors (MOSFET M1-M6). The amount of transistors is not limited to certain number.

The phase error is proportional to

$$Fref \cdot \frac{Δ N}{N} .$$

Where N is the integer number and ΔN is output number of Delta-Sigma modulator. The charge pump and its compensation circuit should generate the current (Icp+ΔIcp), where ΔIcp is the compensation portion of charge pump current generated by the compensation circuit charge pump current Icp. Where

$$Δ Icp = Icp \cdot \frac{Δ N}{N} .$$

As it is shown in FIG. 3, the ground 32 connects to the source terminals of both transistors M1 and M2. Where the drain terminal of M1, connecting to the gate terminal of M1, receives charge pump current Icp 31, also links and supplies signal 33 to the gates of both M1 and M2. The drain of M2, on the other hand, links to the source terminal of M3. Charge pump current Icp also supplies signals to all the drain terminals of transistors M3, M4, M5, and M6, where all the source terminals are connected 34 to the same signal source Icp. The gate terminals of said transistors M3, M4, M5 and M6 all receive signals 35 from M2's drain terminal as the M2 drain terminal, while connects to M3 drain terminal, also links to the gate terminals of M3, M4, M5 and M6. The drain terminals of transistors M4, M5 and M6 produce a number of ΔN outputs 36. Compensation portion of charge pump current ΔIcp can be accumulated by this ΔN, and

$$Δ Icp = Icp \cdot \frac{Δ N}{N} .$$

1. A compensated fractional-N synthesizer comprising:
a voltage controlled oscillator providing a frequency output signal;
a frequency divider dividing said frequency output signal, generating a frequency divider output divided signal; said frequency divider receiving controlling signal from an adder, said adder receiving a fractional signal from a sigma-delta modulator and an independent integer number signal;
a phase frequency detector comparing a reference frequency signal with said frequency divider output divided signal outputting a phase frequency detector output to a charge pump;
a loop filter for filtering a current, said loop filter providing a filtered current to said voltage controlled oscillator;
a charge pump for providing said current; and
a charge pump compensation means having a plurality of switch transistors providing an output signal to said charge pump, said charge pump compensation means receiving said fractional signal from said sigma-delta modulator.

2. The compensated fractional-N synthesizer of claim 1, wherein the charge pump compensation generates current equal to (Icp+ΔIcp), where ΔIcp is the charge pump compensation current.

3. The compensated fractional-N synthesizer of claim 1, wherein the charge pump compensation circuit has six capacitors.

4. A charge pump compensation device for fractional number frequency synthesizing comprising:
a voltage controlled oscillator creating a frequency signal;
a voltage controlled oscillator divider receiving the signal from said voltage controlled oscillator; whereas said voltage controlled oscillator divider dividing said signal received from said voltage controlled oscillator according to an output from an adder; wherein said adder receives an integer number and an output from a sigma delta modulator;
wherein said sigma delta modulator receives a fractional number and creates an output received by said adder;
a phase frequency detector receiving an output from the voltage controlled oscillator divider, the phase frequency detector receiving a fixed reference frequency input;
a loop filter to filter a current, the loop filter providing a filtered current to the voltage controlled oscillator; and
a charge pump means comprising a charge pump and a charge pump compensation for providing the current, said charge pump controllable by the phase frequency detector; said charge pump compensation receiving a sigma delta modulator output.

5. The charge pump compensation device of claim 4, wherein said charge pump compensation generates current equal to (Icp+ΔIcp), where ΔIcp is the charge pump compensation current.

6. The charge pump compensation device of claim 4, wherein said charge pump compensation comprises a plurality of switch transistors.

7. The charge pump compensation device of claim 4, wherein said phase frequency detector receives and compares said divided output from said voltage controlled oscillator divider, with a fixed reference frequency input.

8. A compensated fractional-N synthesizer comprising:
a phase locked loop comprising a voltage controlled oscillator, a frequency divider, a phase frequency detector and a loop filter;
a charge pump having a charge pump compensation receiving an modulated fractional number input; said charge pump receiving a signal from said phase frequency detector and providing a signal to said loop filter;
wherein said frequency divider receives a controlled signal from an adder, said adder receiving a plurality of frequency number inputs.

9. The compensated fractional-N synthesizer of claim 8, wherein said phase frequency detector compares a frequency divider output signal with a fixed reference frequency input signal.

10. The compensated fractional-N synthesizer of claim 8, wherein said charge pump compensation generates current equal to (Icp+ΔIcp), where ΔIcp is the charge pump compensation current.

11. The compensated fractional-N synthesizer of claim 8, wherein said frequency number input further comprises an integer number input and a modulated fractional number input.

12. The compensated fractional-N synthesizer of claim 11 wherein said modulated fractional number input is modulated by a Sigma-Delta modulator.
